(19) United States
(12) Patent Application Publication
(10) Pub. No.: US 2012/0068553 A1
(43) Pub. Date: Mar. 22, 2012

(54) Apparatus for Adaptively Reducing Electromagnetic Wave

(76) Inventor: Jin Ock Jung, Incheon (KR)

(21) Appl. No.: 13/322,892

(22) PCT Filed: May 31, 2010
(86) PCT No.: PCT/KR10/03445

§ 371 Date: Nov. 28, 2011

(30) Foreign Application Priority Data
May 29, 2009 (KR) 10-2009-0047585

(51) Int. Cl. H03K 3/013

(52) U.S. Cl. 307/106

(57) ABSTRACT

Disclosed is an apparatus for adaptively reducing electromagnetic waves that reduces electromagnetic waves generated from commercial power by changing a grounding point of the commercial power supplied to a home. The apparatus for reducing electromagnetic waves includes an electromagnetic wave generator, an electromagnetic wave detector, an impedance varying unit, and a controller. The electromagnetic wave generator is connected to a secondary coil terminal of an external transformer to generate electromagnetic waves. The electromagnetic wave detector generates detection signals corresponding to the electromagnetic waves generated from the electromagnetic wave generator, and the impedance varying unit varies the impedance for a grounding point in the electromagnetic wave generator. The controller controls the impedance varying unit such that the impedance for the grounding point in the impedance varying unit, where the electromagnetic waves are minimized is selected, in accordance with the detection signal from the electromagnetic wave generator. According to the above configuration, it is possible to reduce electromagnetic waves by varying the impedance for all loads in a home with only one apparatus for reducing electromagnetic waves and remove an unnecessary configuration substantially having no effect on varying the impedance. Accordingly, it is possible to provide an apparatus for reducing electromagnetic waves that can reduce a possibility of misoperation at a low manufacturing cost with a simple circuit.

### TECHNICAL FIELD

The present invention relates to an apparatus for adaptively reducing electromagnetic waves, and more particularly, to an apparatus for reducing electromagnetic waves generated by commercial power, by changing a grounding point of the commercial power supplied to a home.

### BACKGROUND ART

In general, commercial AC power is supplied to a home or offices through a single phase two-wired or a single phase three-wired socket. Electronic devices using AC power, such as televisions and computers, generate electromagnetic waves, which influence operation of other electromagnetic devices and cause misoperation, and have an adverse effect on a human body.

A principle that the amount of electromagnetic wave generated from the input side changes in accordance with the position of the grounding point of the AC power is known. An apparatus that maintains a grounding state where the amount of electromagnetic wave is small, by converting the grounding state of the input side of AC power into a grounding state where the smallest amount of electromagnetic wave is generated has been disclosed in Korean Patent No. 0592730.

FIGS. 1 and 2 are FIGS. 2 and 5, respectively, on Korean Patent No. 0592730.

As shown in FIG. 1, a grounding line detecting/grounding apparatus of the above patent includes a first terminal 10a and second terminal 10b, a power source 30, a detecting unit 50, a pulse generator 40, a grounding selector 60, a controller 70, a display 80, a switch 91, and body socket terminals 20a, 20b, and 20c.

When the first terminal 10a and the second terminal 10b are connected to sockets in home or an office, the grounding line detecting/grounding apparatus receives commercial AC power. The body socket terminals 20a, 20b, and 20c are terminals connecting electronic products, such as TVs or computers, to the grounding line detecting/grounding apparatus. Accordingly, the commercial AC power inputted through the first terminal 10a and the second terminal 10b is supplied to the electronic products through the body socket terminals 20a, 20b, and 20c. The switch 91 allows or stops power supply to the electronic products through the grounding line detecting/grounding apparatus by operation of a user.

The power source 30 converts the AC power supplied from the first terminal 10a and the second terminal 10b into DC power and the detecting unit 50 detects electromagnetic waves generated from the power source 30, using an antenna therein. The pulse generator 40 generates pulses in proportion to the amount of electromagnetic wave detected by the detecting unit 50 and the controller 70 drives the grounding selector 60 in accordance with the magnitude and width generated by the pulse generator 40. The display 80 displays the state of the current electromagnetic wave to the outside.

FIG. 2 is a diagram showing in detail the configuration of the grounding selector 60 of FIG. 1. As shown in FIG. 2, the grounding selector 60 includes a first relay 61, a second relay 62, a first impedance C5 and R5, and second impedance C6 and R6.

The first impedance C5 and R5 and the second impedance C6 and R6 are implemented by an RC parallel circuit having capacitors C5 and C6 and resistances R5 and R6, respectively.

The first relay 61 selectively grounds the first terminal 10a and the second terminal 10b in accordance with the control of the controller 70. Further, the second relay 62 varies the impedance of the grounding side of the first terminal 10a or the second terminal 10b by being switched in accordance with the control of the controller 70.

For example, in the state shown in FIG. 2, when the second relay 62 is turned on, the first terminal 10a is grounded through the first impedance C5 and R5 and the second impedance C6 and R6. On the other hand, when the second relay 62 is turned off in the state shown in FIG. 2, the first terminal 61 is grounded through the first impedance C5 and R5. Accordingly, the first terminal 10a and the second terminal 10b can have four grounding states by the grounding selector 60, in accordance with combination of operation of the first relay 61 and the second relay 62.

However, the grounding line detecting/grounding apparatus of Korean Patent No. 0592730 has the following problems:

First, electronic products, such as TVs or computers, which are the object to reduce generation of electromagnetic waves, are connected to the body socket terminals 20a, 20b, and 20c, such that one grounding line detecting/grounding apparatus can reduce the electromagnetic waves of only one electronic product.

Therefore, the user has to be provided with a grounding line detecting/grounding apparatus for each electronic product to reduce the amount of generation of electromagnetic waves, and connect the device to a socket, then connect the grounding line detecting/grounding apparatus to the electronic products.

Second, in the configuration of the grounding selector 60 shown in FIG. 2, four types of impedance selection, that is, grounding line selections can be theoretically implemented in accordance with combination of switching states of the two relays 61 and 62, but practically, two types of impedance selection are possible. This is because even if the first relay 61 selects any one of the first terminal 10a and the second terminal 10b, the results are the same for the characteristics of the AC power, such that it cannot practically change the grounding point. Further, the grounding line detecting/grounding apparatus is used with the connection state maintained once it is connected to a socket and this is because the first relay 61 is provided to deal with changes in connection state although the connection state is not practically changed, which is an unnecessary part.

As a result, the grounding line detecting/grounding apparatus of the related art selects whether the second impedance C6 and R6 is additionally selected by the second relay 62, while the first impedance C5 and R5 is ordinary selected. This configuration of a circuit unnecessarily adds the first relay 61, complicates the control method of the controller 70 for controlling the first relay 61, increases the manufacturing cost of products, and increases possibility of misoperation. When the grounding line detecting/grounding apparatus of the related art is actually manufactured, the same results are obtained in both two switching states of the first relay 61, which confuses determination of the controller 70 so as not to determine appropriate switching, and accordingly, misoperation increasing electromagnetic waves frequently occurs.

Third, in the configuration of the grounding selector 60 shown in FIG. 2, both of the impedances 61 and 62 are implemented by RC parallel circuits, such that changes in impedance are not large in changing the switching states of the second relay 62 for changing the grounding point; therefore, it is difficult to remarkably reduce the electromagnetic waves.

That is, in general, impedances are implemented by pure resistances, RC circuits, or RL circuits, and the impedances in electronic circuits are usually implemented by pure resistances or RC parallel circuits. This is because the RL circuits are likely to affect other elements of the circuits by inducing generation of magnetic flux. However, in the circuit of FIG. 2, since the first impedance C5 and R5 is implemented by the RC parallel circuit and the second impedance C6 and R6 is also implemented by the RC parallel circuit, the magnitude of the entire impedance is necessarily limited by the same types of impedances. Theoretically, although it is possible to increase changes in impedance by increasing the change between the R value and the C value of the first impedance C5 and R5 and the second impedance C6 and R6, the range of the value of the capacitance where appropriate operation is possible in accordance with the range of the magnitude of the voltage and current of the power inputted through the first terminal 10a and the second terminal 10b, is such that it is actually difficult to increase the change in impedance.

### DISCLOSURE OF INVENTION

### Technical Problem

Accordingly, it is one object of the present invention to remove inconvenience of providing an apparatus for reducing electromagnetic waves for each electronic product by reducing electromagnetic waves of commercial power itself such that one apparatus can reduce electromagnetic waves for all electronic products, while adaptively reducing electromagnetic waves generated from the commercial power supplied to home.

It is another object of the present invention to provide an apparatus for adaptively reducing electromagnetic waves that reduces possibility of misoperation at a low manufacturing cost with a simple circuit, by removing a substantially unnecessary configuration while implementing a function of varying a grounding line by varying the impedance.

It is the other object of the present invention to provide an apparatus for adaptively reducing electromagnetic waves having a simple circuit that makes it possible to increase a difference in impedance, when changing the switching state for changing the grounding point.

### Solution to Problem

In order to accomplish the above objects, the present invention provides an apparatus for adaptively reducing electromagnetic waves, comprising: a electromagnetic wave generator that is connected to a secondary coil terminal of a transformer converting the AC power supplied from the outside into commercial power, so as to generate electromagnetic waves corresponding to the electromagnetic waves generated from the secondary coil; an electromagnetic wave detector that detects the electromagnetic waves generated from the electromagnetic wave generator and generates detection signals corresponding to the detected electromagnetic waves; an impedance varying unit that varies impedance for a grounding point in the electromagnetic wave generator; and a controller that controls the impedance varying unit such that the impedance for the grounding point in the impedance varying unit, where the electromagnetic waves are minimized is selected, in accordance with the detection signal from the electromagnetic wave generator. Wherein, the impedance varying unit includes a switch for selecting a resistance, and an RC parallel circuit, and any one of the resistance and the RC parallel circuit, and the controller selects any one of the resistance and the RC parallel circuit by controlling the switch and connects the selected one to the grounding point.

Preferably, the electromagnetic wave generator includes a sub-transformer that has the secondary coil terminal of the transformer as an input. Preferably, the electromagnetic wave generator includes a rectifier supplying DC power for operation of the apparatus for reducing electromagnetic waves, by converting the output of the secondary coil terminal of the sub-transformer into a direct current. Preferably, the sub-transformer has a center tap at a primary coil therein.

Preferably, the electromagnetic wave detector includes an antenna receiving the electromagnetic waves generated from the electromagnetic wave generator, and the electromagnetic wave generator further includes a pulse generator that generates pulses corresponding to the electromagnetic wave received through the antenna. Preferably, the controller considers the pulses larger than a predetermined reference magnitude and/or a predetermined reference width in the pulses generated by the pulse generator as the detection signals.

### Advantageous Effects of Invention

According to the present invention, it is possible to reduce electromagnetic waves by varying the impedance for all loads in a home with only one apparatus for reducing electromagnetic waves and remove an unnecessary configuration substantially having no effect on varying the impedance. Accordingly, it is possible to provide an apparatus for reducing electromagnetic waves that can reduce a possibility of misoperation at a low manufacturing cost with a simple circuit.

### BRIEF DESCRIPTION OF DRAWINGS

The above objects, features and advantages of the present invention will become more apparent to those skilled in the related art in conjunction with the accompanying drawings. In the drawings:

FIGS. 1 and 2 are FIGS. 2 and 5, respectively, on Korean Patent No. 0592730, as an example of an apparatus for reducing electromagnetic waves of the related art;

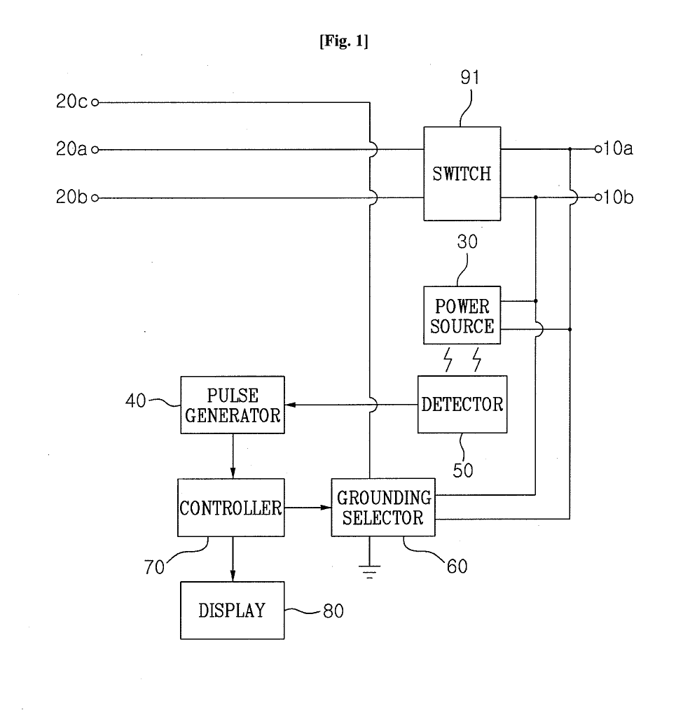

FIG. 3 is a view showing the outer appearance of an apparatus for adaptively reducing electromagnetic waves according to the present invention;

FIG. 4 is a block diagram showing the internal configuration of the apparatus for adaptively reducing electromagnetic waves of FIG. 3;

FIG. 5 is a diagram showing the internal configuration of the electromagnetic wave generator of FIG. 4;

FIG. 6 is a diagram showing an example of a pulse generated by the pulse generator of FIG. 4; and

FIG. 7 is a diagram showing a circuit configuration of the impedance varying unit of FIG. 4.

### BEST MODE FOR CARRYING OUT THE INVENTION

Hereinafter, the present invention will be described with reference to the accompanying drawings.

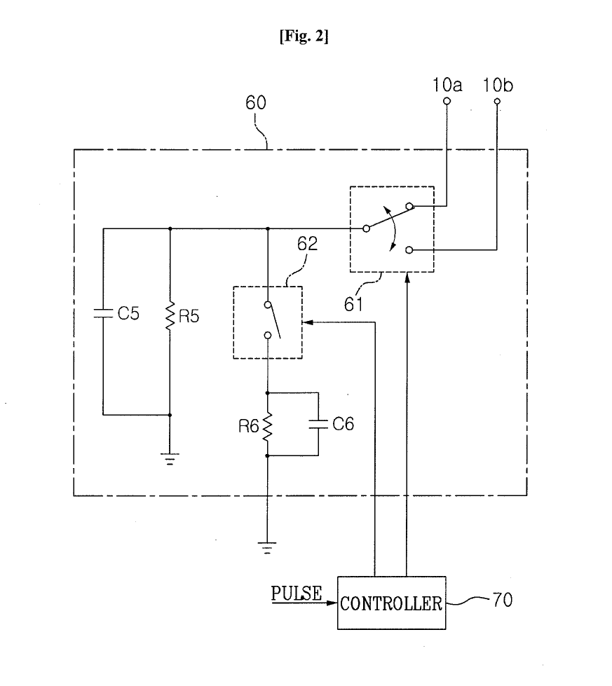

FIG. 3 is a view showing the outer appearance of an apparatus for adaptively reducing electromagnetic waves according to the present invention.

The apparatus for adaptively reducing electromagnetic waves 100 according to the present invention includes a circuit for reducing electromagnetic waves in a casing 110, and a first terminal 111, a second terminal 112, and a third terminal 113 inserted and connected to sockets in a home or an office are installed outside the casing 110. The first terminal 111 and the second terminal 112 are terminals receiving AC power and the third terminal 113 is a grounding terminal connected to the grounding side. The casing 110 is manufactured in a size that is suitable for the apparatus for adaptively reducing electromagnetic waves 100 to a socket.

Unlike Korean Patent No. 0592730 described above, the apparatus for adaptively reducing electromagnetic waves 100 according to the present invention does not have a specific terminal that is connected to an electronic product, and this is because the apparatus for adaptively reducing electromagnetic waves of the present invention was designed not to reduce electromagnetic waves for one load (electronic product), but reduce electromagnetic waves for the commercial power itself, which is supplied to all the loads in the home. Therefore, the apparatus for adaptively reducing electromagnetic waves 100 of the present invention can be connected to any socket in the home, but preferably, it is connected to a socket closest to the transformer that transforms the AC power supplied from the outside into the commercial power supplied to the home, for example, a socket that is located neat to the cabinet panel installed in the home in the circuit, among the sockets in the home.

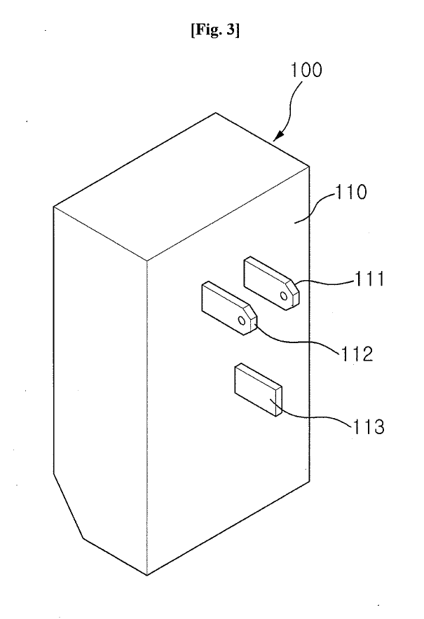

FIG. 4 is a block diagram showing the internal configuration of the apparatus for adaptively reducing electromagnetic waves of FIG. 3. The apparatus for adaptively reducing electromagnetic waves according to present invention includes an electromagnetic wave generator 120, an electromagnetic wave detector 130, a controller 140, an impedance varying unit 150, and a display 160.

The AC power supplied from the outside is inputted to a primary coil 201 of the transformer 200 usually installed outside of the home and finally converted and outputted in commercial power by a secondary coil 202. Simply describing the configuration of the transformer 200 installed outside of the home, the transformer 200 includes the primary coil 201 and the secondary coil 202, and the primary coil 201 and the secondary coil 202 are provided with a grounding wire, respectively, as shown in FIG. 4. Further, the primary coil 201 and the secondary coil 202 are provided with center taps 201a and 202a, respectively.

As described above, the apparatus for adaptively reducing electromagnetic waves is connected to the secondary coil 202 of the transformer 200 by connecting the first terminal 111 and the second terminal 112 in parallel to the secondary coil 202. In this configuration, the third terminal 113 is connected to the grounding wire for the secondary coil 202 of the transformer 200.

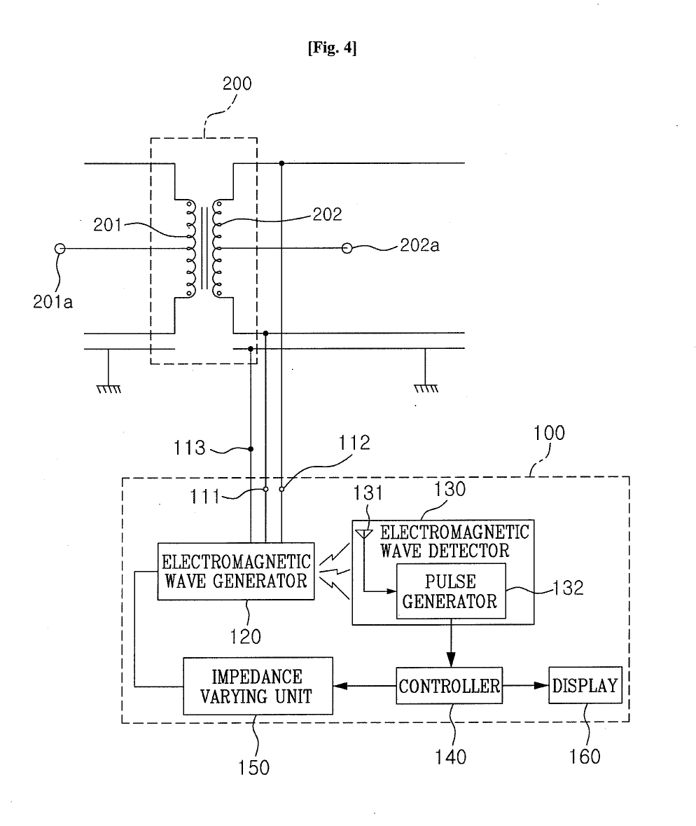

The electromagnetic wave generator 120 generates electromagnetic waves, using the power supplied from the secondary coil 202. The electromagnetic wave generator 120 can implement any types of circuit which can generate electromagnetic waves, using commercial power supplied from the secondary coil 202. FIG. 5 is a diagram showing an example of the electromagnetic wave generator 120.

As shown in FIG. 5, the electromagnetic wave generator 120 of this embodiment includes a sub-transformer 120a and a rectifier 120b.

The sub-transformer 120a includes a primary coil 121 and a secondary coil 122, in which two input terminals and a grounding terminal of the primary coil 121 are connected to the first terminal 111, the second terminal 112, and the third terminal 113, respectively. The primary coil 121 has a center tap 121a. The rectifier 120b, for example, is implemented by a bridge diode circuit and converts the AC power outputted from the output end of the secondary coil 122 into DC power. In operation, the output Vout of the rectifier 120b supplies DC power required for the operations of the elements in the apparatus for adaptively reducing electromagnetic waves 100 of the present invention.

According to this configuration, electromagnetic waves corresponding to the electromagnetic wave noise generated from the secondary coil 202 of the transformer 200 are generated by the sub-transformer 120a connected in parallel with the secondary coil 202 of the transformer 200. Therefore, the sub-transformer 120a is in charge of the main function of the electromagnetic wave generator 120, the rectifier 120b generates DC power for the operation of the apparatus for reducing electromagnetic waves itself, and accordingly, the electromagnetic wave generator 120 substantially functions as the power source.

The electromagnetic wave detector 130 detects electromagnetic waves generated from the electromagnetic wave generator 120 and generates detection signals corresponding to the detected electromagnetic waves. As shown in FIG. 4, the electromagnetic wave detector 130 includes an antenna 131 and a pulse generator 132. The antenna 131 receives the electromagnetic waves generated from the electromagnetic wave generator 120. The pulse generator 132 generates pulses corresponding to the electromagnetic waves received from the antenna 131. The pulses generated by the pulse generator 132 are transmitted to the controller 140.

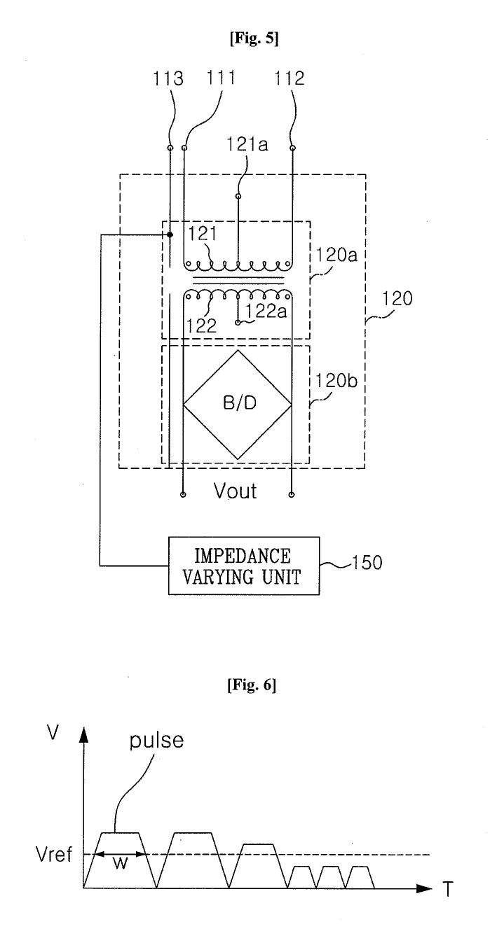

The controller 140 considers pulses larger than a predetermined reference magnitude and/or a predetermined reference width in the pulses generated by the pulse generator 132, as detection signals. That is, FIG. 6 shows an example of the pulses generated by the pulse generator 132, in which there are pulses having the magnitude larger and smaller than a reference magnitude Vref and having the width larger and smaller than a reference width W in the pulses generated by the pulse generator 132, and the controller 140 considers only the pulses larger than the reference magnitude Vref and/or the reference width W in the pulses as detection signals, which are pulses induced by the electromagnetic waves. However, only the pulses having a large magnitude in the momentary pulses can be considered as detection signals, when the detection signals are determined on the basis of only the reference magnitude Vref, and the pulses having a very small magnitude may be considered as detection signals when the detection signals are determined on the basis of only the reference width W. Therefore, it is preferable that the detection signals are considered when both of the reference magnitude Vref and the reference width W are larger than the predetermined reference value, as described above.

The controller 140 controls the impedance varying unit 150 such that the grounding point where the electromagnetic wave is the minimum is selected, in accordance with the detection signals received from the electromagnetic wave detector 130.

The impedance varying unit 150 is connected to the grounding terminal of the primary coil 121 of the sub-transformer 120a in the electromagnetic wave generator 120, as shown in FIGS. 4 and 5, to vary the impedance of the grounding terminal of the primary coil 121 of the sub-transformer 120a. Accordingly, the impedance varying unit 150 substantially minimizes generation of electromagnetic waves by changing the grounding point of the primary coil 121.

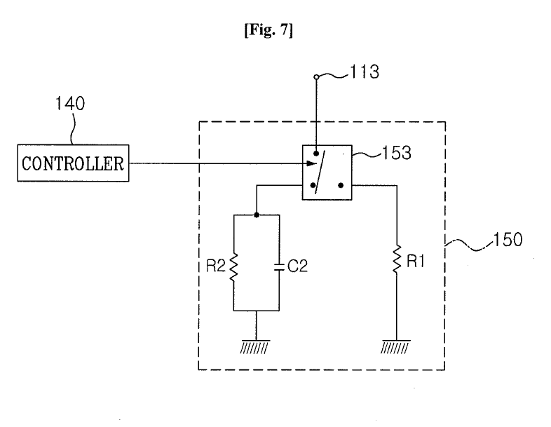

FIG. 7 is a diagram showing a circuit configuration of the impedance varying unit 150 of FIG. 4. The impedance varying unit 150 is composed of a first impedance R1, a second impedance R2 and C2, and a switch 153. The first impedance R1 is implemented by pure resistances, the second impedance R2 and C2 may be implemented by an RC parallel circuit, and the switch 153 is implemented by relays.

The controller 140 selects and connects any one of the first impedance R1 and the second impedance R2 and C2 to the secondary coil 202 by controlling the switch 153. In this configuration, the controller controls the switching state of the switch 153 such that small detection signals are generated from the pulse generator 132 and small electromagnetic waves are generated from the electromagnetic wave generator 120. Accordingly, the impedance changes such that the generation of the electromagnetic waves is minimized at the primary coil 121 of the sub-transformer 120a and the grounding point correspondingly changes such that the electromagnetic waves are minimized.

The controller 140 can control the switch 153 to generate small electromagnetic waves in various ways.

For example, when detection signals above a predetermined number per unit time are detected from the pulse generator 132, the controller 140 compares the detection signals for all of the first impedance R1 and the second impedance R2 and C2 by changing the switching state of the switch 153, and selects the switching state where small detection signals are detected. The comparison of two switching states described above can be performed when the number of detection signals per unit time is above a predetermined level, periodically at regular time intervals, and may be modified in various ways.

Meanwhile, in the present invention, the primary coil 121 of the sub-transformer 120a has a center tap 121a, as shown in FIG. 5. This corresponds to a case where the transformer 200 supplying commercial power to the home has itself a center tap 201a. That is, electromagnetic waves accurately corresponding to the electromagnetic waves generated from the secondary coil 202 of the transformer 200 can be substantially acquired from the primary coil 121 of the sub-transformer 120a by forming the primary coil 121 of the sub-transformer 120a such that the same environment as the environment generating electromagnetic wave noise in the transformer 200 is achieved.

### INDUSTRIAL APPLICABILITY

According to the present invention described above, an apparatus for reducing electromagnetic waves is not provided for each load (electronic product), while it is possible to perform the operation of reducing electromagnetic waves by varying the impedance for all the loads in the home with only one apparatus for reducing electromagnetic waves, such that it has the advantage of increasing convenience for the users.

Further, an unnecessary configuration that has substantially no effect on varying impedance is removed, such that it is possible to achieve a simple circuit, reduce misoperation, and reduce the manufacturing cost.

Further, according to the present invention, since the impedances that are variably selected are implemented by resistances and an RC parallel circuit, changes in impedance are larger as compared with when two RC parallel circuits are used, such that it is possible to effectively change the grounding point and simplify the circuit.

Although the present invention has been described in connection with the exemplary embodiments illustrated in the drawings, it is only illustrative. It will be understood by those skilled in the art that various modifications and equivalents can be made to the present invention. Therefore, the true technical scope of the present invention should be defined by the appended claims.

1. An apparatus for adaptively reducing electromagnetic waves, comprising:
a electromagnetic wave generator that is connected to a secondary coil terminal of a transformer converting the AC power supplied from the outside into commercial power, so as to generate electromagnetic waves corresponding to the electromagnetic waves generated from the secondary coil;
an electromagnetic wave detector that detects the electromagnetic waves generated from the electromagnetic wave generator and generates detection signals corresponding to the detected electromagnetic waves;
an impedance varying unit that varies impedance for a grounding point in the electromagnetic wave generator; and
a controller that controls the impedance varying unit such that the impedance for the grounding point in the electromagnetic wave generator, where the electromagnetic waves are minimized is selected, in accordance with the detection signal from the electromagnetic wave detector,
wherein the impedance varying unit includes a switch for selecting a resistance, and an RC parallel circuit, and any one of the resistance and the RC parallel circuit, and
the controller selects any one of the resistance and the RC parallel circuit by controlling the switch and connects the selected one to the grounding point.

2. The apparatus according to claim 1, wherein the electromagnetic wave generator includes a sub-transformer that has the secondary coil terminal of the transformer as an input.

3. The apparatus according to claim 2, wherein the electromagnetic wave generator includes a rectifier supplying DC power for operation of the apparatus for reducing electromagnetic waves, by converting the output of the secondary coil terminal of the sub-transformer into a direct current.

4. The apparatus according to claim 2, wherein the sub-transformer has a center tap at a primary coil therein.

5. The apparatus according to claim 1, wherein the electromagnetic wave detector includes an antenna receiving the electromagnetic waves generated from the electromagnetic wave generator.

6. The apparatus according to claim 5, wherein the electromagnetic wave generator further includes a pulse generator that generates pulses corresponding to the electromagnetic wave received through the antenna.

7. The apparatus according to claim 6, wherein the controller considers the pulses larger than a predetermined reference magnitude and/or a predetermined reference width in the pulses generated by the pulse generator as the detection signals.
